(19) United States
(12) Patent Application Publication
(10) Pub. No.: US 2025/0120187 A1
(43) Pub. Date: Apr. 10, 2025

(54) VEHICLE PARTS WITH INTEGRATED PHOTOVOLTAIC ELEMENTS, VEHICLES CONTAINING SUCH VEHICLE PARTS, AND METHODS OF MAKING SUCH VEHICLE PARTS

(71) Applicants: GM Global Technology Operations LLC, Detroit, MI (US); McMaster University, Hamilton (CA)

(72) Inventors: Taeyoung HAN, Troy, MI (US); Shyh-yeu JAO, Bloomfield Hills, MI (US); Valerie Sue MALANEY, West Bloomfield, MI (US); Yujie GUO, Thornilll (CA); Ian J. SUTHERLAND, Gresse Pointe, MI (US); Rafael KLEIMAN, Hamilton (CA); Manoj VISHWAKARMA, Hamilton (CA); Jennifer BAUMAN, Cambridge (CA)

(21) Appl. No.: 18/480,985

(22) Filed: Oct. 4, 2023

(51) Int. Cl. H01L 31/049; B60L 8/00

(52) U.S. Cl. CPC H10F 19/85; B60L 8/003

(57) ABSTRACT

A vehicle part with at least one integrated photovoltaic element includes a part body, at least one area of a barrier layer disposed on at least a portion of the surface of the part body; and at least one photovoltaic element disposed over an area of the barrier layer. Paint covers the portions of the surface of the part body surrounding the photovoltaic elements. A method of making a vehicle part having at least one integrated photovoltaic element includes applying at least one area of a barrier layer on at least a portion of the surface of the part and applying at least one photovoltaic element over an area of the barrier layer. A protective layer is applied over the surface of the photovoltaic element, the surface of the part is painted, and the protective layer can then be removed to expose the photovoltaic element.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to vehicle parts, and in particular to vehicle parts with integrated photovoltaic elements, as well as to vehicles containing such parts, and methods of manufacturing such parts.

Providing electric power to vehicles is a continuing goal for vehicle designers and manufacturers, particularly with the increased interest in electrically powered and hybrid vehicles. Solar power is a readily available source of power, but mounting discrete photovoltaic elements onto vehicle surfaces can be difficult, and can impair the aerodynamic function and detract from the stylized appearance of the vehicle.

### SUMMARY

Embodiments of this disclosure provide vehicle parts with integrated photovoltaic elements. Further embodiments provide vehicles containing vehicle parts with integrated photovoltaic elements. Still further embodiments of this disclosure provide for methods of making vehicle parts with integrated photovoltaic elements.

According to a first embodiment of this disclosure, a vehicle part with at least one integrated photovoltaic element is provided. This vehicle part is preferably a part with a surface that is exposed (or exposable) to light, such as a trunk lid, hood, roof, door panel, or fender. Such parts are typically (but not necessarily) made of metal, such as steel or aluminum.

There is preferably at least one area of a barrier layer disposed on at least a portion of the surface of the part body. The barrier layer is preferably of a non-conductive (i.e., an electrically insulating) material, such as an enamel. There is preferably at least one, and more preferably, a plurality of, photovoltaic elements disposed over an area of the barrier layer. These elements can be built up from one or more layers of material. There can be one or more areas of the barrier layer on the surface of the part, and each area can have one or more photovoltaic elements. In some embodiments electrically conductive traces can be disposed on the part, to interconnect the photovoltaic elements and/or connect the photovoltaic elements to a battery or other storage device or an electric load.

According to a second embodiment of this disclosure, a vehicle is provided with one or more parts having at least one integrated photovoltaic element. These one or more parts preferably have surfaces that are exposed (or exposable) to light, such as a trunk lid, hood, roof, door panel, or fender. Such parts are typically (but not necessarily) made of metal, such as steel or aluminum.

There is preferably at least one area of a barrier layer disposed on at least a portion of the surface of the part. The barrier is preferably of a non-conductive (i.e., an electrically insulating) material, such as an enamel. There is preferably at least one photovoltaic element disposed over an area of the barrier layer. These photovoltaic elements can be built up from one or more layers of material. There can be one or more areas of the barrier layer on the surface of the part, and each area can have one or more photovoltaic elements. In some embodiments, electrically conductive traces can be disposed on the part to interconnect the photovoltaic elements and/or connect the photovoltaic elements to a battery or other storage device or to an electric load.

According to a third embodiment of this disclosure, a method of making a vehicle part with at least one integrated photovoltaic element is provided. This vehicle part is preferably a part with a surface that is exposed (or exposable) to light, such as a trunk lid, hood, roof, door panel, or fender. Such parts are typically (but not necessarily) made of metal, such as steel or aluminum.

According to this method an area of a barrier layer is preferably applied to a portion of the surface of the part. The barrier layer is preferably made of a non-conductive (i.e., an electrically insulating) material, such as an enamel. At least one photovoltaic element is applied over the area of the barrier layer. This photovoltaic element can be built up from one or more layers of material. One or more areas of the barrier layer can be applied to the surface of the part, and one or more photovoltaic elements can be applied to each area of the barrier layer. In some embodiments, electrically conductive traces can be applied over the part to part so that the photovoltaic elements are interconnected and/or the photovoltaic elements can be connected to a battery or other storage device or to an electrical load.

In accordance with this third embodiment, removable protective covers are applied over the photovoltaic elements. A layer of paint or other aesthetic coating is then applied over the surface of the part. Thereafter, the protective covers are removed from the regions of photovoltaic elements, exposing the surface of the photovoltaic elements. A protective coating is applied over the surfaces of the part, covering the photovoltaic elements and the surrounding surfaces of the part. This protective coating is preferably transparent to the light that is utilized by the photovoltaic elements.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a top plan view of a vehicle part in the form of a vehicle hood with integrated photovoltaic elements, according to the principles of the first embodiment of this disclosure;

FIG. 2 is a top plan view of a first alternate construction of a vehicle part in the form of a vehicle hood with multiple integrated photovoltaic elements on each area of barrier layer, according to the principles of the first embodiment of this disclosure;

FIG. 3 is a top plan view of a first alternate construction of a vehicle part in the form of a vehicle hood with multiple integrated photovoltaic elements on each area of barrier layer and traces interconnecting the photovoltaic elements, according to the principles of the first embodiment of this disclosure;

FIG. 4 is a top plan view of a vehicle with multiple parts having at least one integrated photovoltaic element, according to the principles of the second embodiment of this disclosure;

FIG. 5 is an exploded view of one possible configuration of a CIGS photovoltaic element useful in the embodiments of this disclosure;

FIG. 6A is a flowchart of a method of making a vehicle part with an integrated photovoltaic element according to the principles of the third embodiment of this disclosure;

FIG. 6B is a flowchart of an alternate method of making a vehicle part with an integrated photovoltaic element according to the principles of the third embodiment of this disclosure;

FIG. 7A is a partial cross-sectional view of a vehicle part after the step of applying an area of a barrier layer on the surface of the part;

FIG. 7B is a partial cross-sectional view of a vehicle part after the step of applying a region of photovoltaic on the area of the barrier layer on the surface of the part;

FIG. 7C is a partial cross-sectional view of a vehicle part after the step of applying removable protective cover on the photovoltaic regions;

FIG. 7D is a partial cross-sectional view of a vehicle part after the step of applying paint or other coating to the surface of the part;

FIG. 7E is a partial cross-sectional view of a vehicle part after the step of removing the paint or other coating and the protective cover from the surface of the photovoltaic elements; and

FIG. 7F is a partial cross-sectional view of a vehicle part after the step of applying a protective coating to finish the part.

In the drawings, reference numbers may be reused to identify similar and/or identical elements.

### DETAILED DESCRIPTION

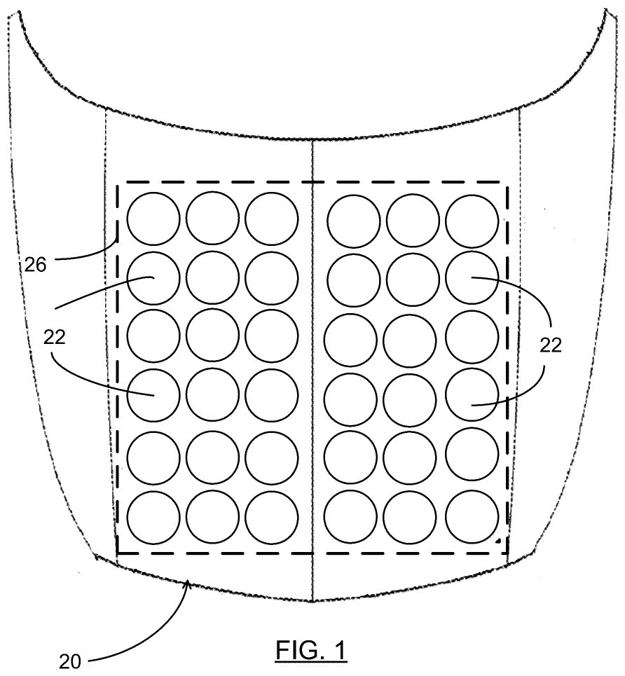

According to a first embodiment of this disclosure, a vehicle part in the form of a vehicle hood with at least one integrated photovoltaic element is indicated generally as 20 in FIG. 1. While this detailed description and accompanying drawings reference a vehicle hood, the disclosure is not so limited, and the vehicle part can be any other part that is exposed (or exposable) to light, such as a trunk lid, roof, door panel, or fender. Such parts are typically (but not necessarily) made of metal, such as steel or aluminum, however the part could be made of polymers or composites.

The vehicle part 20 has at least one photovoltaic element 22 integrated thereon, and preferably more than one photovoltaic element thereon. Each photovoltaic element 22 is preferably formed by depositing one, and more preferably a plurality of constituent layers on an area 26 of barrier layer on the surface of the part. The photovoltaic elements are preferably a CIGS thin film, but they could be some other thin-film photovoltaic material suitable for generating electricity from incident solar radiation, such as Cd—Te, amorphous silicon, or perovskite.

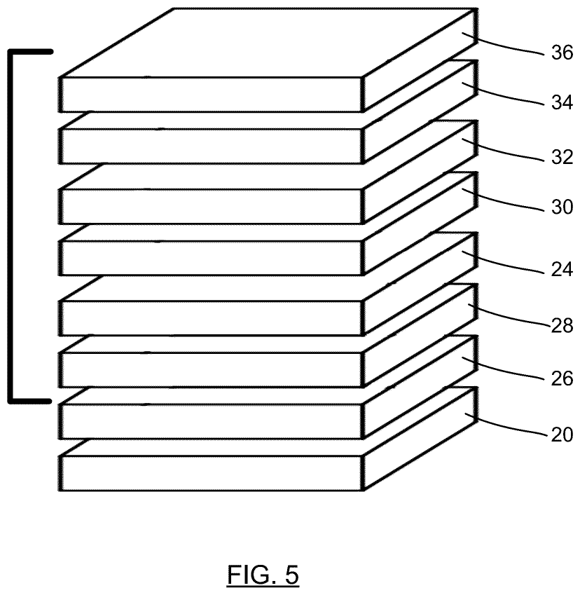

As shown in FIG. 5 the photovoltaic element 22 can comprise a molybdenum back contact layer 28, followed by the CIGS photovoltaic element layer 24, a Zn(O,S) layer 30, an i-ZnO layer 32, an indium-tin and oxide (ITO) layer 34, and a magnesium fluoride (MgF₂) layer 36.

The barrier layer is preferably electrically insulating (i.e., non-electrically conductive). In this embodiment the barrier layer is an enamel, comprising fused glass (SiO₂) frit, which may have various additives to adjust its physical properties such as adhesion and melting point. In addition to providing electrical isolation, the barrier layer preferably provides a smooth surface for supporting the photovoltaic elements 22. Of course, some other type of material could be used.

The areas 26 of the barrier layer can conform to the contours of the part 20.

Similarly, the thin-film photovoltaic elements 22 which are preferably formed on the barrier layer, can conform to the contours of the area of barrier layer on which they are disposed.

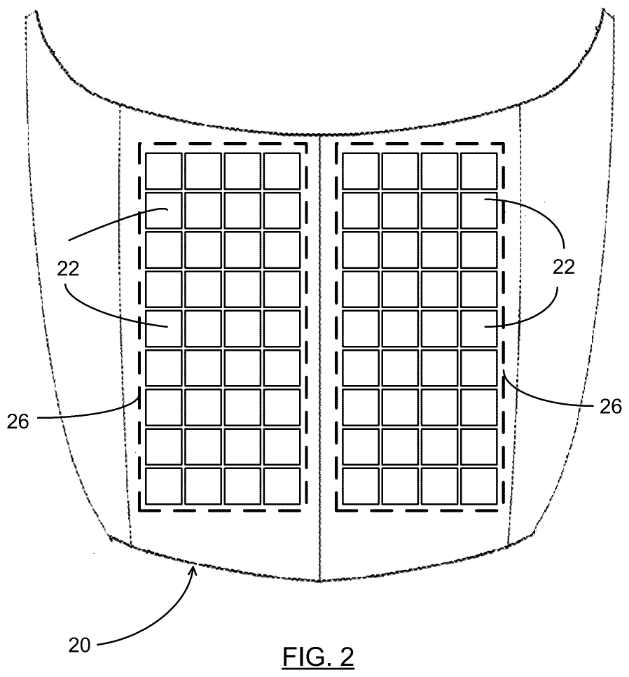

As shown in FIG. 1, there can be a single area 26 of barrier layer on the part 20, on which a plurality of individual photovoltaic elements 22 are individually formed. As shown in FIG. 2, there can be multiple areas 26 of boundary layer on the part 20, on which a single photovoltaic element is formed and divided into a plurality of photovoltaic elements 22 (for example by laser trimming). In general there can be one or more areas 26 of boundary layer on the part, depending on the geometry of the part and the logistics of the application process. In general these areas 26 are applied at the same time so that the subsequent application of areas 26 of boundary layer does not disturb the previously applied areas. Similarly, there can be one or more photovoltaic elements 22 applied to each area 26 of boundary layer. A design consideration is to limit the size of the photovoltaic elements 22 to thereby limit the amount of current generated by each element that must be transmitted. Rather than individually forming a plurality of individual photovoltaic elements, it will generally be more efficient to form a single large photovoltaic element, and divide it into a plurality of photovoltaic elements 22 for example with a laser, or by mechanical or chemical removal. In all of these constructions, the total area of the photovoltaic elements is preferably substantially co-extensive with its corresponding area 26 of barrier layer, to maximize energy collection.

Preferably, a layer 38 of paint or other coating covers the surface of the part, except for the collection surfaces of the photovoltaic elements 22, and a protective clear coat 40 covers the entire surface, including the collection surfaces of the photovoltaic elements. This protective layer 40 provides protection of the painted surfaces as well as of the collection surface of the photovoltaic elements 22, and is preferably transparent to the light that the photovoltaic elements 22 use to generate electricity.

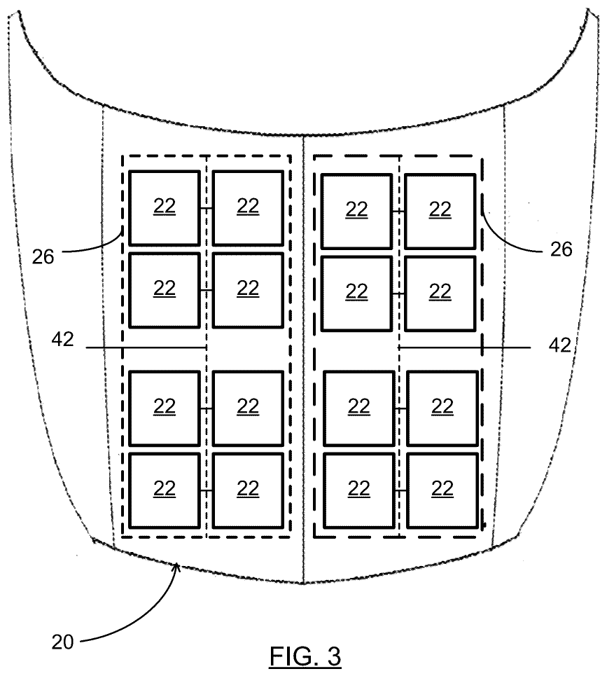

As shown in FIG. 3, in some embodiments a network of electrically conductive traces 42 of copper or other conductive material can be applied over the surface of the part to interconnect the photovoltaic elements 22 and/or to connect the photovoltaic elements to a storage device (e.g. a battery), or an electric load. The photovoltaic elements 22 are preferably formed such that separate electrical connections can be conveniently made with the bottom and the top layers of the photovoltaic elements from above. Alternatively portions of the network of traces 42 could be applied to the areas 26 of the barrier layer before the photovoltaic elements are formed thereon.

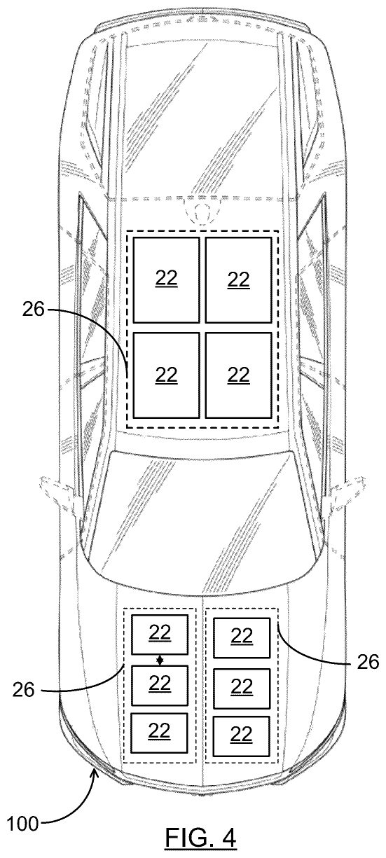

According to a second embodiment of this disclosure, a vehicle having a part with at least one integrated photovoltaic element is indicated generally as 100 in FIG. 4. While this detailed description and accompanying drawings reference a vehicle with photovoltaic elements integrated in the hood and roof, the disclosure is not so limited, and the vehicle can include photovoltaic elements incorporated into any other part that is exposed (or exposable) to light, such as a trunk lid, door panel, or fender. Such parts are typically (but not necessarily) made of metal, such as steel or aluminum but could also be made of polymers or composites.

As shown in FIG. 4, the vehicle 100 has at least one part, and in this embodiment two parts (hood and roof) with at least one, and preferably a plurality of photovoltaic elements 22 integrated thereon. The photovoltaic elements 22 are formed on areas 26 of barrier layer on the surface of the vehicle 100. The photovoltaic elements 22 are preferably CIGS elements, as described above, but they could be some other thin-film photovoltaic material suitable for generating electricity from incident solar radiation, such as Cd—Te, amorphous silicon, or perovskite. The photovoltaic elements 22 are preferably directly deposited in one or more layers onto the areas 26 of barrier layer, although in some applications they could be applied over one or more intervening layers on the barrier layer.

The barrier layer is preferably electrically insulating (i.e., non-electrically conductive). In this embodiment the barrier layer is an enamel comprising fused glass (SiO₂) frit, which may have various additives to adjust its physical properties such as adhesion and melting point. In addition to providing electrical isolation, the barrier layer provides a smooth surface for the photovoltaic elements 22. Of course, the barrier layer can be of some other enamel material, or some other type of material, that can provide a thin, smooth, electrically insulating surface.

The areas 26 of the barrier layer can conform to the contours of the vehicle parts. Similarly, the photovoltaic elements 22 can conform to the contours of the areas 26 of the barrier layer on which they are disposed.

There can be one or more areas 26 of the barrier layer on the surface of the vehicle, and there can be one or more photovoltaic elements 22 on each area of barrier layer. In some instances, there is one area 26 of barrier layer on which a plurality of photovoltaic elements 22 are disposed, such as on the roof of the vehicle 100 in FIG. 4. In other instances, there are multiple areas 26 of barrier layer on which a plurality of photovoltaic elements 22 are disposed, such as on the hood of the vehicle 100 in FIG. 4. The photovoltaic elements 22 are preferably substantially co-extensive with the area 26 of barrier layer on which they are disposed.

A layer 38 of paint or other coating covers the surface of the vehicle 100, except for the collection surfaces of the photovoltaic elements 22. A further protective layer 40 of clear coat can be provided over the surface of the vehicle 100, including the collection surfaces of the photovoltaic elements 22. This protective layer 40 provides protection of the painted surfaces as well as of the collection surfaces of the photovoltaic elements 22, and is preferably transparent to the light that the photovoltaic elements use to generate electricity.

According to a third embodiment of this disclosure, a method of making a vehicle part with at least one integrated photovoltaic element is provided, such as the part 20 shown in FIGS. 1-3. This part can be integrated with other parts to assemble a vehicle 100 as shown in FIG. 4. This vehicle part is preferably a part with a surface that is exposed (or exposable) to light, such as a trunk lid, hood, roof, door panel, or fender. Such parts are typically (but not necessarily) made of metal, such as steel or aluminum.

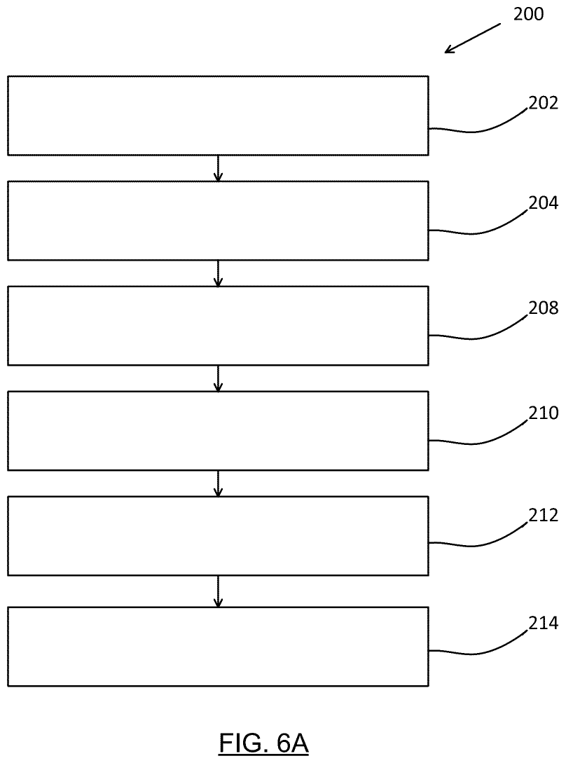

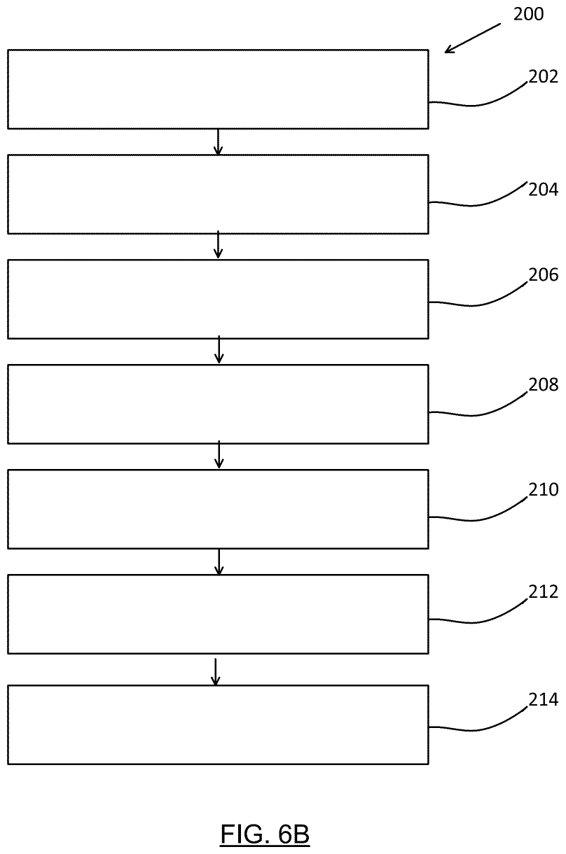

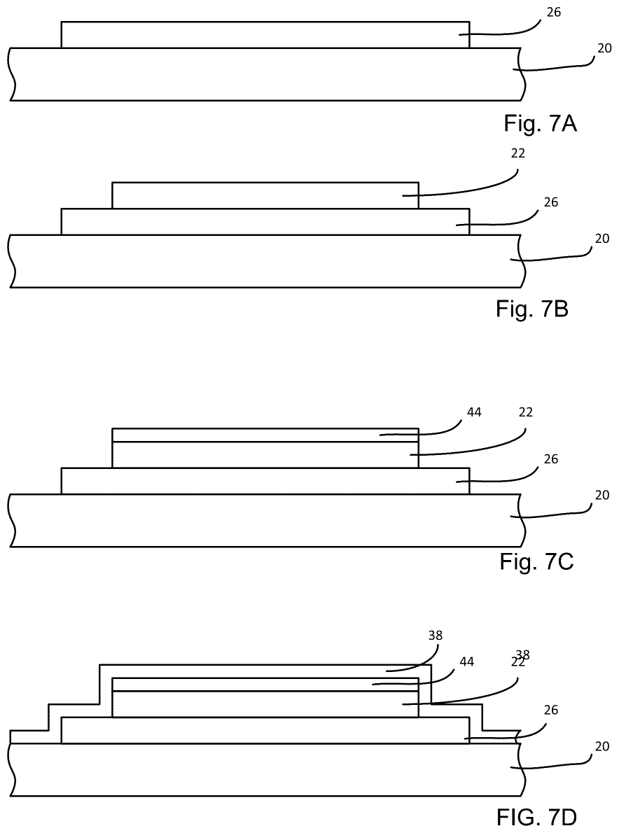

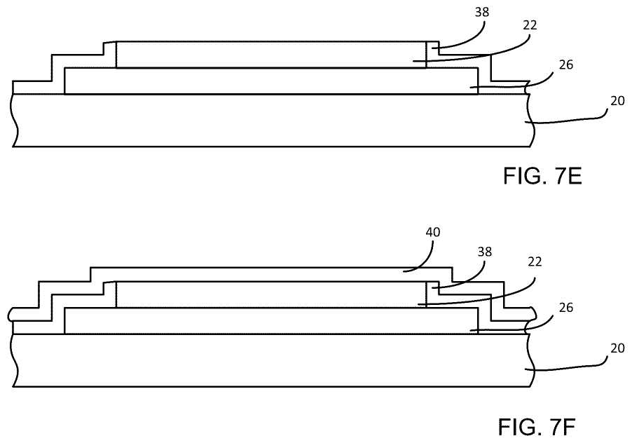

This method 200 is illustrated schematically in FIGS. 6A and 6B. According to this method the surface of the part is cleaned, and at 202 an area of a barrier layer is applied to at least a portion of the surface of the part body, such as area 26 described above with respect to part 20, and shown in FIG. 7A. The barrier layer is preferably made of a non-conductive (i.e., an electrically insulating) material, such as an enamel made of fused glass frit. This enamel is preferably applied as a slurry including glass frit powder sprayed on the surface of the part, and fused in place by firing at 750-800° C. using halogen lamps, to form a barrier layer about 100 m thick. One large area 26 of barrier layer can be applied to the part, or several smaller areas of barrier layer can be applied to the part, depending upon the size and the configuration of the part. The barrier layer can provide a number of advantages, including providing corrosion protection for the part, acting as a diffusion barrier from the metal part into photovoltaic element layers, providing electrical isolation from the vehicle body, and planarizing (smoothing) the rough surface of the part. Instead of an enamel, the barrier layer could be made of other suitable, electrically insulating material.

At 204, at least one photovoltaic element 22 is applied over the area of the barrier layer. This element can be built up from one or more layers of material, or one or more layers of different materials with a series of physical and chemical deposition steps, as described above and shown in FIG. 5. One or more photovoltaic elements can be applied to each area of the barrier layer, such as the elements 22 on area 26, as shown in FIG. 7B. One suitable thin-film photovoltaic material is copper indium gallium selenide (CIGS) Other suitable photovoltaic materials include those based upon cadmium telluride (Cd—Te), or amorphous silicon, or perovskite.

In some embodiments (as illustrated in FIG. 6B), at 208 after the photovoltaic elements 22 are deposited on the areas 26 of the barrier layer, electrically conductive traces 42 can be applied to the areas of the photovoltaic elements and the barrier layer, so that the photovoltaic elements can be interconnected and/or the photovoltaic elements can be connected to a battery or other storage device, or to an electrical load. The traces 42 can be made of metal, such as copper or a copper alloy, or of an electrically conductive polymer, such as traces 42 shown in FIG. 3. The traces 42 can be applied in a variety of ways, but in this embodiment they can be applied with 3-D printing.

In accordance with this third embodiment, at 208 a removable protective cover 44 is applied over the collection surfaces of photovoltaic elements 22 as shown in FIG. 7C. The removable protective cover 44 can be plies of a polymer such as polyethylene that are adhered over the surfaces of the photovoltaic elements 22. In one alternative, the protective covers 44 can be a layer of a polymer or other suitable material that is applied over the photovoltaic elements, for example with 3-D printing. In another alternative, the protective covers can be a layer of curable polymer or other suitable material that is applied over the entire surface of the part, and only cured (for example with UV light) over the surfaces of the photovoltaic elements, and the uncured materials removed (for example with solvent washing).

At 210 the part can be painted, preferably using a conventional process, as shown in FIG. 7D. A primer and a base coat can be applied to the part. A typical paint process might include cleaning the part, subjecting it to a dip in resin and pigment, typically using electrodeposition in a bath to coat all exposed surfaces, and baking (typically at about 171° C. for 25 minutes) to set the material. Then a primer can be applied to the part, and the part baked (typically at 131° C. for 25 minutes) to cure the primer. Finally, a base coat and/or a top coat is applied to the part.

After painting, at 212, the protective covers 44 on the surfaces of the photovoltaic elements 22 can be removed, which removes the paint layer 38 that would otherwise impair the function of the photovoltaic elements 22, as shown in FIG. 7E. Depending upon the nature of the protective cover 44, the covers can be removed mechanically by peeling or rubbing, thermally by heating or melting, or chemically by dissolution. After the protective covers are removed, at 214, the entire surface of the part can be treated with a protective coating to protect the finish of the paint, and to protect the surface of the regions of photovoltaic material, as shown in FIG. 7F. The applied clear coat is typically baked (typically at 129° C. for 25 minutes). The clear coat acts as a hermetic and transparent layer that also provides mechanical and chemical protection for the photovoltaic elements. The properties of this protective coating are selected so that it does not materially interfere with the function of the photovoltaic elements 22, which typically functions on visible light.

In some embodiments the part may be combined with other vehicle parts, for example by welding either before or after the areas of barrier layer and the photovoltaic elements are applied. The resulting part or assembly of parts has integrated photovoltaic elements that can be used to power features in the vehicle in which the part is incorporated, or to charge a storage device such as a battery or batteries. Because the photovoltaic elements are formed on the part itself, difficulties in mounting premanufactured photovoltaic elements are eliminated, and overall a larger area of the surface of the part or part assembly can be provided with photovoltaic capabilities.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

What is claimed is:

1. A vehicle part with at least one integrated photovoltaic element, the vehicle part comprising:
a part body;
at least one area of a barrier layer disposed on at least a portion of the surface of the part body;
at least one photovoltaic element disposed over an area of the barrier layer; and
a layer of paint covering the portions of the surface of the part body surrounding the at least one photovoltaic element.

2. The vehicle part according to claim 1 wherein the barrier layer is electrically insulating.

3. The vehicle part according to claim 2 wherein the barrier layer comprises enamel.

4. The vehicle part according to claim 2 wherein there are a plurality of photovoltaic elements disposed on an area of the barrier layer.

5. The vehicle part according to claim 2 wherein there are a plurality of areas of barrier layer on the surface of the part, and at least one photovoltaic element on each area.

6. The vehicle part according to claim 2 wherein each photovoltaic element comprises a plurality of layers.

7. The vehicle part according to claim 2 further comprising a network of conductive traces interconnecting portions of the photovoltaic elements.

8. The vehicle part according to claim 1 wherein the vehicle part is at least one trunk lid, a hood, a roof, a door panel, and a fender.

9. A vehicle having at least one part with at least one integrated photovoltaic element, the part comprising:
a part body;
at least one area of a barrier layer disposed on at least a portion of the surface of the part body;
at least one photovoltaic element disposed over an area of the barrier layer; and
a layer of paint covering the portions of the surface of the part body surrounding the photovoltaic element.

10. The vehicle according to claim 9 wherein the barrier layer on the part is electrically insulating.

11. The vehicle according to claim 9 wherein the barrier layer on the part comprises enamel.

12. The vehicle according to claim 9 wherein there are a plurality of photovoltaic elements disposed on an area of barrier layer.

13. The vehicle part according to claim 9 wherein there are a plurality of areas of barrier layer on the surface of the part, and at least one photovoltaic element on each area of barrier layer.

14. The vehicle according to claim 9 wherein each photovoltaic element comprises a plurality of layers.

15. The vehicle according to claim 12 further comprising a network of conductive traces interconnecting portions of the photovoltaic elements.

16. The vehicle according to claim 9 wherein the vehicle part is at least one trunk lid, a hood, a roof, a door panel, and a fender.

17. A method of making a vehicle part having at least one integrated photovoltaic element, the method comprising:
applying at least one area of a barrier layer on at least a portion of the surface of the part;
applying at least one photovoltaic element over an area of the barrier layer; and
applying a protective layer over the surface of the photovoltaic element;
painting the surface of the part;
removing the protective layer to expose the surface of the photovoltaic element.

18. The method of making a vehicle part according to claim 17, further comprising the step of applying a protective coating over the surface of the part, including the painted surfaces and the photovoltaic elements.

19. The method according to claim 17 wherein the vehicle part is at least one trunk lid, a hood, a roof, a door panel, and a fender.

20. The method according to claim 17 where a plurality of photovoltaic elements are formed on an area of the barrier layer, and further comprising the step of applying electrically conductive pathways to connect to the photovoltaic elements.
